(19) United States
(12) Patent Application Publication
(10) Pub. No.: US 2008/0149990 A1
(43) Pub. Date: Jun. 26, 2008

(54) MEMORY SYSTEM WITH POLY METAL GATE

(75) Inventors: Connie Pin Chin Wang, Mountain View, CA (US); Paul R. Besser, Sunnyvale, CA (US); Simon Siu-Sing Chan, Saratoga, CA (US); YouSeok Suh, Cupertino, CA (US); Shenqing Fang, Fremont, CA (US)

Correspondence Address: FARJAMI & FARJAMI LLP, 26522 LA ALAMEDA AVENUE, SUITE 360, MISSION VIEJO, CA, 92691, US

(73) Assignees: SPANSION LLC, Sunnyvale, CA (US); ADVANCED MICRO DEVICES, INC., Sunnyvale, CA (US)

(21) Appl. No.: 11/735,241

(22) Filed: Apr. 13, 2007

Related U.S. Application Data
(60) Provisional application No. 60/871,421, filed on Dec. 21, 2006.

(51) Int. Cl. H01L 29/788; H01L 21/336

(52) U.S. Cl. 257/316; 438/257; 257/E29.3; 257/E21.422

(57) ABSTRACT

A memory system includes a substrate, forming an insulator over the substrate, forming a gate layer over the insulator, forming a stability layer over the gate layer, and forming a conductive layer over the stability layer.

### TECHNICAL FIELD

The present invention relates generally to memory systems, and more particularly to a system for non-volatile memory.

### BACKGROUND ART

Whether its smart phones, personal digital assistants, location based devices, digital cameras, music players, computers, or transportation, electronics devices have become an integral part of many daily activities. While we take for granted the convenience and utility of these electronic devices, it is often not apparent just how much storage is needed for capacity and retention. Thus, various types of non-volatile memories have been developed including electrically erasable programmable read only memory (EEPROM) and electrically programmable read only memory (EPROM). Each type of memory had advantages and disadvantages. EEPROM can be easily erased without extra exterior equipment but with reduced data storage density, lower speed, and higher cost. EPROM, in contrast, is less expensive and has greater density but lacks erasability.

Another type of memory called “Flash” EEPROM, or Flash memory, has become popular as it combines advantages of high density and low cost characteristic of EPROM but with the electrical erasability of EEPROM. Flash memory can be rewritten and hold its contents without supplying continuous power. Contemporary Flash memories are designed in a floating gate or a charge trapping architecture. Each of the architectures has advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored informing may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture that result in decrease in data retention.

The charge trapping architecture offers improved scalability with new semiconductor processes versus the floating gate architecture. One implementation of the charge trapping architecture is a silicon-oxide-nitride-oxide semiconductor (SONOS) where charge is trapped in a nitride layer. Leakage and charge-trapping efficiency are two major parameters considered in device performance evaluation. Charge-trapping efficiency determines if enough charge remains in the storage nodes after program/erase operation and is reflected in retention characteristics. It is especially critical when the leakage behavior of storage devices is inevitable.

SONOS Flash memories suffer from poor programming performance. Silicon content in the nitride layer improves the programming and erasing performances but offers poor data retention. Although silicon content plays an important role in charge-trapping efficiency, it does not have same constructive effect on leakage characteristics. The interface between the charge trapping layer with both the top blocking oxide layer and the bottom tunneling oxide layer present both scaling and functional problems as well as add cost to the manufacturing process.

There continue to be concerns regarding the erasing and programming processes, since too high a voltage or too much current can damage the memory cell. In order to perform an erase without damaging the memory cell a process of erase, verify, and repeat is used. This iterative approach helps to protect the individual memory cells, but severely restricts the performance of the memory array.

Similarly, when data is programmed into the memory cell it is difficult to accurately end the write process at the proper resistance value. Applying too much current may damage the memory cell and applying too little current yields unreliable data retention. This conventional approach of updating memory cells is too slow. The erasing and programming limitations present significant issues to non-volatile memory manufacturers. A new approach must be found in order to increase the performance of non-volatile memory.

Thus, a need still remains for a memory system to improve erase performance. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a substrate, forming an insulator over the substrate, forming a gate layer over the insulator, forming a stability layer over the gate layer, and forming a conductive layer over the stability layer.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top plan view of a memory system in an embodiment of the present invention;

FIG. 2 is a more detailed top plan view of a portion of the memory system;

FIG. 3 is a cross-sectional view of the poly metal gate of the memory system;

FIG. 4 is a cross-sectional view of a poly metal gate in an alternative embodiment of the present invention;

FIGS. 5A, 5B, and 5C are schematic views of electronics systems as examples in which various aspects of the present invention can be implemented; and

FIG. 6 is a flow chart of a memory system for manufacturing the memory system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the invention, regardless of its orientation. The term “vertical” refers to a direction perpendicular to the horizontal as just defined. Terms, such as “on” “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

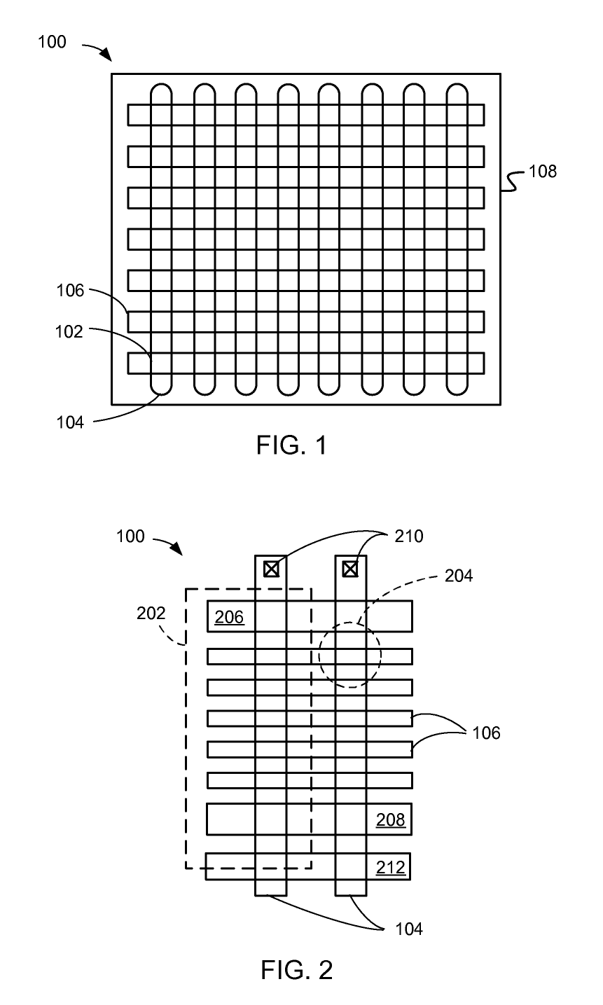

Referring now to FIG. 1, therein is shown a top plan view a memory system 100 in an embodiment of the present invention. The memory system 100 may be used in a number of different memory architectures, such as NOR or NAND architecture. The memory system 100 includes a poly metal gate 102 in an overlap region of bit lines 104, such as a source-drain and word lines 106. The poly metal gate 102 is formed having improved thermal stability and improved chemical stability. The poly metal gate 102 provides storage of an electrical charge, such as electrons.

The memory system 100 also includes a substrate 108 such as a semiconductor substrate. As an example the substrate 108 can be a p-type substrate, having a first region (not shown), formed as an n-type region, and a second region (not shown), formed as an n-type region. The first region can function as a source or a drain while the second region can function as a drain or a source as a compliment of the first region. The first region, the second region, or a combination thereof can be electrically equivalent to the bit lines 104 providing access to the memory system 100 for decoding processes. Signals on the word lines 106 and connection of the bit lines 104 to an electrical source or drain can enable the memory system 100 to read, program or erase.

For illustrative purposes, the memory system 100 is shown having a plurality of the poly metal gate 102, although it is understood that any number of the poly metal gate 102 may be included. It is also understood that each of the poly metal gate 102 may provide storage for any number of electrical charges.

Referring now to FIG. 2, therein is shown a more detailed top plan view of a portion of the memory system 100. The top view depicts two instances of memory sections 202, such as NAND memory strings. The memory sections 202 have memory cells 204, including the poly metal gate 102 of FIG. 1, between a drain select line 206 and a source select line 208. The memory cells 204 have the word lines 106 and the bit lines 104, wherein the word lines 106 and the bit lines 104 can be substantially perpendicular one to the other. The drain select line 206 and the source select line 208 can also be substantially perpendicular to the bit lines 104. Contacts 210, such as drain contacts, are on the bit lines 104 near the drain select line 206. A source line 212 is substantially perpendicular to the bit lines 104 and near the source select line 208.

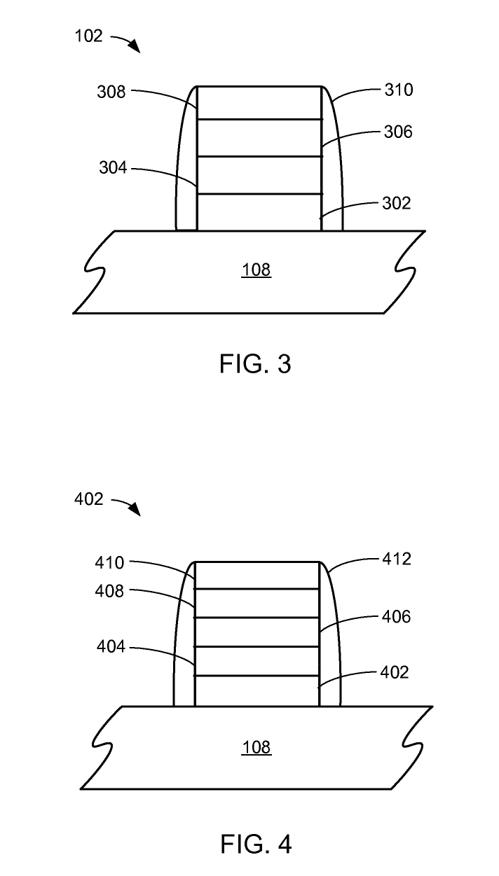

Referring now to FIG. 3, therein is shown a cross-sectional view of the poly metal gate 102 of the memory system 100. The poly metal gate 102 includes an insulator 302, such as a gate dielectric or oxide-nitride-oxide (ONO) film stack, over the substrate 108. A gate layer 304, such as a polysilicon layer, is formed over the gate dielectric 302. The poly metal gate 102 also includes a stability layer 306, such as a tungsten nitride (WN). The stability layer 306 can be formed with a thickness of about twenty angstroms to one hundred angstroms. A conductive layer 308, such as a tungsten silicide layer (WSiₓ), can be formed over the stability layer 306. The conductive layer 308 can be about one hundred angstroms to about one thousand angstroms thick. The stability layer 306 stabilizes the conductive layer 308 and provides a barrier to the gate layer 304.

The conductive layer 308 can be applied without the need to be a stable phase, such as tungsten silicide (WSi₂), or without the need to provide stoichiometrics to the poly metal gate 102. The stability layer 306 further provides a barrier eliminating fluorine (F) attacks on silicon thus enabling additional processes for deposition, such as chemical vapor deposition or physical vapor deposition, of the conductive layer 308. The poly metal gate 102 significantly reduces unintended etching during processing such as chemical cleaning including post etch polymer removal. The poly metal gate 102 can also include a spacer 310 such as an oxide, an oxynitride, or a silicon nitride. The spacer 310 can provide optimized processing of the memory system 100. For optimized processing, the spacer 310 can be formed along an outer edge of the conductive layer 308, the stability layer 306, the gate layer 304, and the gate dielectric 302.

The stability layer 306 and the conductive layer 308 can be applied by a process such as physical vapor deposition of reactive sputtering of silicon nitride using a tungsten target with nitride plasma. Similarly, the stability layer 306 and the conductive layer 308 can be applied by a process such as, physical vapor deposition with direct current sputtering of tungsten nitride or tungsten silicide. Further, the stability layer 306 and the conductive layer 308 can be applied by a process such as, chemical vapor deposition of tungsten nitride using WF₆/SiH₄/NH₃ or WF₆/B₂H₆/NH₃. Yet further, the stability layer 306 and the conductive layer 308 can be applied by a process such as, chemical vapor deposition of tungsten silicide using either WF₆/SiH₄ or WF₆/Si₂H₆. Post annealing can be used to enhance electrical, crystal, or chemical stability.

It has been discovered that the poly metal gate 102 significantly improves chemical stability of the memory system 100.

Referring now to FIG. 4, therein is shown a cross-sectional view of a poly metal gate 400 in an alternative embodiment of the present invention. In a manner similar to structure of FIG. 3, the poly metal gate 400 includes an insulator 402, such as a gate dielectric or oxide-nitride-oxide (ONO) film stack, over the substrate 108. A gate layer 404, such as a polysilicon layer, if formed over the gate dielectric 402. The poly metal gate 400 also includes a protective layer 406, such as tungsten-flash (W-Flash). The protective layer 406 can be formed with a thickness of about ten angstroms to about one hundred angstroms. A stability layer 408, such as tungsten nitride, can be formed over the protective layer 406. A conductive layer 410, such as tungsten (W), can be formed over the stability layer 408 and the protective layer 406. The stability layer 408 and the protective layer 406 stabilize the conductive layer 410 and provide a barrier to the gate layer 404.

The conductive layer does not react with silicon in a process, such as an anneal process of one thousand degrees for thirty minutes. The protective layer 406 provides an interfacial oxide between tungsten and silicon. The poly metal gate 400 can also include a spacer 412 such as an oxide, an oxynitride, or a silicon nitride. The spacer 412 can provide optimized processing of the memory system 100. For optimized processing, the spacer 412 can be formed along an outer edge of the conductive layer 410, the stability layer 408, the protective layer 406, the gate layer 404, and the gate dielectric 402.

It has been discovered that the poly metal gate 400 significantly improves thermal stability of the memory system 100.

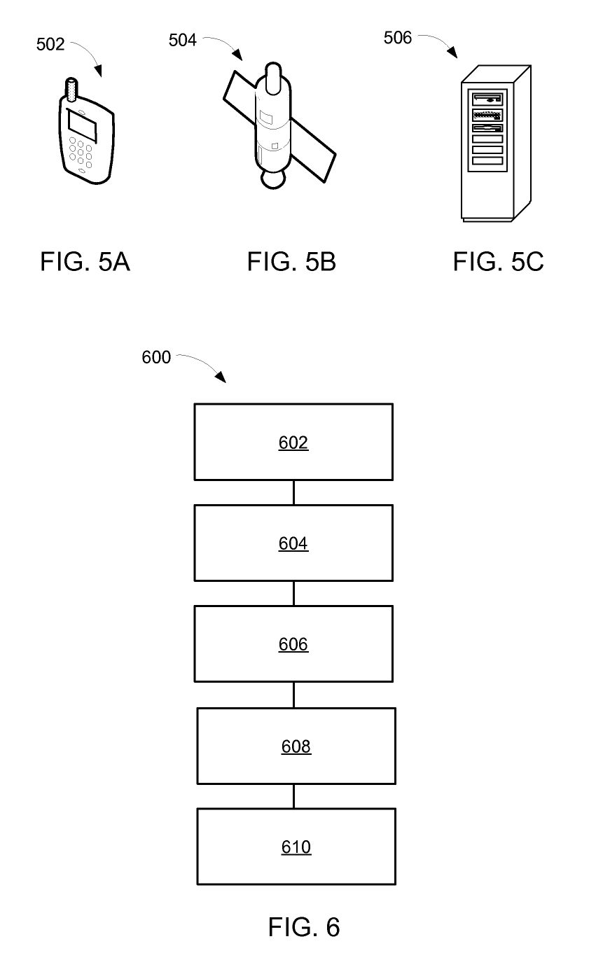

Referring now to FIGS. 5A, 5B, and 5C therein is shown schematic views of electronics systems as examples in which various aspects of the present invention can be implemented. The electronics systems can be any system performing any function including creation, transportation, transmittal, modification, or storage of data. As examples, electronics systems such as a smart phone 502, a satellite 504, and a compute system 506 can include the present invention. For example, information created, transported, or stored on the smart phone 502 can be transmitted to the satellite 504. Similarly, the satellite 504 can transmit or modify the information to the compute system 506 wherein the information can be stored, modified, or transmitted by the compute system 506.

Referring now to FIG. 6, therein is shown a flow chart of a memory system 600 for manufacturing the memory system 100 in an embodiment of the present invention. The system 600 includes providing a substrate in a block 602; forming an insulator over the substrate in a block 604; forming a gate layer over the insulator in a block 606; and forming a stability layer over the gate layer in a block 608; and forming a conductive layer over the stability layer in a block 610.

In greater detail, a system to provide the method and apparatus of the memory system 100, in an embodiment of the present invention, is performed as follows:
1. Providing a semiconductor substrate.
2. Forming a gate dielectric over the semiconductor substrate.
3. Forming a gate layer over the gate dielectric.
4. Forming a stability layer as a barrier to the gate layer.
5. Forming a conductive layer isolated from the gate layer and over the stability layer.

The present invention thus has numerous aspects.

A principle aspect of the present invention is improved resistivity in the poly metal gate with small line dimensions. The present invention is unique in that typically resistivity increases significantly due to small line issues.

Another aspect is that the present invention improves thermal stability. The present invention is unique in that typically, during processing when temperatures are greater than eight hundred degrees Celsius, layer formation is not well controlled, and voids may form.

Yet another aspect of the present invention is that the present invention improves chemical stability. The present invention is unique in that typically during processing, such as chemical cleaning including post etch polymer removal, metal layers can be easily etched away making integration difficult.

Yet another aspect of the present invention is that the protective layer slows down the incidental formation of tungsten silicide. The present invention is unique in that typically during processing tungsten nitride loses nitride and the tungsten reacts with silicon to form unintended tungsten silicide.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the memory system method and apparatus of the present invention furnish important and heretofore unknown and unavailable solutions, capabilities, and functional aspects for memory systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A method for forming a memory system comprising:
providing a substrate;
forming an insulator over the substrate;
forming a gate layer over the insulator;
forming a stability layer over the gate layer; and
forming a conductive layer over the stability layer.

2. The method as claimed in claim 1 wherein forming the conductive layer includes forming a tungsten silicide layer.

3. The method as claimed in claim 1 wherein forming the gate layer includes forming a protective layer.

4. The method as claimed in claim 1 wherein forming the conductive layer includes forming a tungsten layer.

5. The method as claimed in claim 1 further comprising forming an electronics system including the memory system.

6. A method for forming a memory system comprising:
providing a semiconductor substrate;
forming a gate dielectric over the semiconductor substrate;
forming a gate layer over the gate dielectric;
forming a stability layer as a barrier to the gate layer; and
forming a conductive layer isolated from the gate layer and over the stability layer.

7. The method as claimed in claim 6 wherein forming the stability layer includes forming a tungsten nitride layer by vapor deposition.

8. The method as claimed in claim 6 wherein forming the conductive layer includes forming a tungsten silicide layer by vapor deposition.

9. The method as claimed in claim 6 wherein forming the gate layer includes forming a protective layer over the gate layer.

10. The method as claimed in claim 6 wherein forming the conductive layer includes forming a tungsten layer by vapor deposition.

11. A memory system comprising:
a substrate;
an insulator over the substrate;
a gate layer over the insulator;
a stability layer over the gate layer; and
a conductive layer over the stability layer.

12. The system as claimed in claim 11 wherein the conductive layer is a tungsten silicide layer.

13. The system as claimed in claim 11 wherein the gate layer is a protective layer.

14. The system as claimed in claim 11 wherein the conductive layer is a tungsten layer.

15. The system as claimed in claim 11 further comprising an electronics system including the memory system.

16. The system as claimed in claim 11 wherein:
the substrate is a semiconductor substrate;
the insulator is a gate dielectric over the semiconductor substrate;
the gate layer is a gate layer over the gate dielectric;
the stability layer is a barrier to the gate layer; and
the conductive layer is a conductive layer isolated from the gate layer and over the stability layer.

17. The system as claimed in claim 16 wherein the stability layer is a tungsten nitride layer having the characteristic of a vapor deposition.

18. The system as claimed in claim 16 wherein the conductive layer is a tungsten silicide layer having the characteristic of a vapor deposition.

19. The system as claimed in claim 16 wherein the gate layer includes a protective layer over the gate layer.

20. The system as claimed in claim 16 wherein the conductive layer is a tungsten layer having the characteristic of a vapor deposition.
